(19) United States
(12) Patent Application Publication
(10) Pub. No.: US 2007/0158733 A1
(43) Pub. Date: Jul. 12, 2007

(54) High-speed low-voltage programming and self-convergent high-speed low-voltage erasing schemes for EEPROM

(75) Inventors: Daniel Huang, Chu-Pei City (TW); Lee Wang, Diamond Bar, CA (US); Hsin Chang Lin, Chu-Pei City (TW); Roget Chang, Chu-Pei City (TW)

Correspondence Address: BIRCH STEWART KOLASCH & BIRCH, PO BOX 747, FALLS CHURCH, VA, 22040-0747, US

(73) Assignee: Yield Microelectronics Corp.

(21) Appl. No.: 11/327,436

(22) Filed: Jan. 9, 2006

(51) Int. Cl. H01L 29/788

(52) U.S. Cl. 257/315

(57) ABSTRACT

The present invention provides a high-speed low-voltage programming scheme and self-convergent high-speed low-voltage erasing schemes for Electrically Erasable Programmable Read-Only Memories (EEPROM). For the N-type Field Effect Transistor (NFET) based NVM programming, an elevated source voltage to the substrate can achieve high efficient Drain-Avalanche-Hot-Electron Injection (DAHEI) into the floating gate resulting in high-speed and low-voltage operations. The self-convergent and low-voltage erasing can be achieved by applying Drain-Avalanche-Hot Hole Injection (DAHHI) with the conditions of restricted maximum drain current and a moderate control gate voltage enough to turn on the NFET. For the p-type FET (PFET) based EEPROM programming, a negative source voltage relative to the substrate can achieve high efficient Drain-Avalanche-Hot-Hole Injection (DAHHI) into the floating gate resulting in high-speed and low voltage operations. The self-convergent and low voltage erasing can be achieved by applying Drain-Avalanche-Hot-Electron Injection (DAHEI) with the conditions of restricted maximum magnitude of drain current and a negative moderate control gate voltage enough to turn on the PFET.

### BACKGROUND OF THE INVENTION

1. Field of the Invention

This invention relates to Electrically Erasable, Programmable Read-Only Memories (EEPROM), and more particularly, to a programming and erasing schemes for EEPROM to enable high-speed low-voltage programming operations and self-convergent high speed low-voltage erasing operations.

2. Description of the Prior Art

Electrically Erasable PROMs depend on the long-term retention of electronic charges as the information-storage mechanism. The charges are stored on a floating polysilicon gate of a MOS device (the term floating refers to the fact that no electrical connection exists to this gate). The charges are transferred from the silicon substrate through an insulator.

Semiconductor Non-Volatile Memories (NVM), and particularly Electrically Erasable, Programmable Read-Only Memories (EEPROM), exhibit wide spread applicability in a range of electronic equipments from computers, to telecommunications hardware, to consumer appliances, and to Subscriber Identity Module (SIM) cards for mobile phones. In general, EEPROMs serve a niche in the NVM space as a mechanism for storing firmware and data that can be kept even with power off and can be altered as needed. The flash EEPROM may be regarded as a specifically configured EEPROM that may be erased only on a global or sector-by-sector basis.

FIG. 1A shows a typical cross-section view of NFET based EEPROM with stacked-gate cell. The NFET EEPROM cell is formed on the P-substrate or P-well 1a. The cell includes source 2a and drain 3a regions formed within the P-substrate 1a, a tunneling dielectric layer 4a formed on the surface of the P-substrate 1a, a floating gate 5a formed on the tunneling dielectric layer 4a, a control dielectric layer 6a formed on top of the floating gate layer 5a. The tunneling dielectric 4a can be formed by oxides. The floating gate 5a is usually formed by poly-silicon. Oxides or other high dielectric insulators usually form the control dielectric layer.

FIG. 1B shows split-gate cell comprising an NMOSFET device with floating gate 5b in between the control gate 7b and substrate 1b. FIG. 2A shows typical cross-section views of PMOSFET based stacked-gate cell, and FIG. 2B shows split-gate cell comprising a PMOSFET device with floating gate 5d in between the control gate 7d and substrate 8d.

In the conventional write-erase schemes for EEPROMs, Drain-Avalanche-Hot Carrier Injection (DAHCI) and Fowler-Nordheim Tunneling (FNT) have been used for programming and erasing, respectively. FIG. 3A shows NFET EEPROM programming conditions according to the prior art while FIG. 4A shows PFET EEPROM programming conditions according to the prior art. Similarly, the conventional Fowler-Nordheim Tunneling (FNT) erasing schemes for the NFET and PFET are shown in FIGS. 6A and 7A, respectively.

For the conventional programming scheme, the source electrode is usually grounded and the control gate and drain electrode are set to a high voltages such that Drain-Avalanche-Hot Carriers Injection (DAHCI) occur in the drain depletion region. It is noticed that in the DAHCI process, most carriers either flow to the drain electrode and the substrate. Only very few hot carriers are injected to the gate. Usually, the gate current is only millions to thousands less than the substrate current. Thus, the programming efficiency using the conventional DAHCI is very low. To get the proper programming speed, it requires higher voltage and higher device current. The other side effect of this higher voltage and higher current operation is that the disturbance to the neighbor cells through the substrate becomes more significant, especially for higher density EEPROM. Those advert effects limit the EEPROM design for higher density leading to lower cost. Therefore, EEPROM device technologists attempt to resolve those issues by various device structures and geometries for scaling down the devices.

Fowler-Nordheim Tunneling (FNT) is the most commonly used for erasing EEPROM cells in the conventional erase scheme. The main issues with the FNT erase are the widely disperse distribution after erase operations and the requirement for very high voltages (about 12 V for a typical oxide thickness). When high voltage is applied to cause tunneling between floating gate and the substrate, microscopically, the tunneling current is not uniform across the source, drain, junction depletion, and channel regions. The most likely and most strong tunneling current occurs close to the source or drain regions. The applied voltage difference will cause variations of electrical fields in source, drain, and junction depletion regions resulting in variations of total tunneling currents. Thus, some EEPROM devices are designed to form a sharp tip in floating gate to restrict the tunneling in small area for the erase operations. The devices have been proven better erase uniformity and lower erase voltage. Most design to battle this wide spread issue is to apply a convergent circuit to fine-tune the device cell erase. However, this approach not only needs more silicon area for the convergent circuit but also requires a lengthy and time-consuming operation procedure.

### SUMMARY OF THE INVENTION

The purpose of the present invention is to provide a method for programming a nonvolatile memory such as EEPROM or Flash EEPROM. The programming efficiency is improved (hundreds to thousands times improvement) and leads to a high-speed, low-voltage, and low-disturbance programming operation.

Another aspect of the present invention is to provide a self-convergent high-speed low-voltage erasing method for the nonvolatile memory, for instance, the EEPROM or Flash EEPROM. The method is not limited to a specific EEPROM structure or geometry. The present invention applies DAHCI for the erase operations. With restricted device maximum drain current and proper gate voltage to turn on the device, the device self-converges to a final erased state and eventually reaches an electrical steady state.

The advantage of the present invention is to provide a low-programming voltage scheme with the features those can relieve the loading for charge pumping circuit and programming disturbance in EEPROMs. It allows designing a smaller charge pumping circuit and increasing EEPROM cell density. For EEPROM erasing scheme, the self-convergent low-voltage erasing can achieve very narrow distributions for the device electrical properties after the erase operations. A convergent circuit is not required in this erasing scheme. The present invention scheme can dramatically improve the NVM cost in terms of densities, sizes, and power. The aspects of the present invention are briefly described as follows.

The Programming Scheme for NFET Based Nonvolatile Memory:

The present invention discloses a method of programming a NFET based nonvolatile memory, comprising: applying on a source a positive source voltage relative to a substrate to create a reversed-bias voltage on a source-substrate junction; and applying a first and a second positive voltages to a control gate and a drain, respectively.

The difference between the first positive voltage and the positive source voltage is greater than the threshold voltage of the nonvolatile memory. The second positive voltage greater than the source voltage is sufficient large to cause DAHCI in the drain depleted region.

The Programming Scheme for PFET Based Nonvolatile Memory:

Another aspect of the present invention is to provide a method of programming a PFET based nonvolatile memory comprising: assuming the substrate or Nwell is grounded; applying on a source a negative source voltage relative to a substrate to create a reversed-bias voltage on a source substrate junction; and applying the first and second negative voltages to a control gate and a drain, respectively.

In the scheme, the absolute value of the difference between the first negative voltage and the negative source voltage is greater than the one of the threshold voltage of the nonvolatile memory. The absolute value of the difference between the second negative voltage and the negative source voltage is sufficient large to cause DAHCI in the drain depleted region.

Further embodiments of programming bias schematics of the preferred embodiments for NFET and PFET are provided. It shall be noted that both NFET and NFET can be implemented with only one high positive voltage Vddh without switching to negative voltages for PFET.

The Erasing Scheme for NFET Based Nonvolatile Memory:

Further aspect of the present invention is to provide a method of self-convergent erasing a NFET based nonvolatile memory having electrons initially stored in a floating gate comprising: applying a moderate positive gate voltage on the NFET gate to turn on the nonvolatile memory; and applying to the drain electrode with a high voltage that is higher than a saturation voltage to create DAHCI in the drain depleted region.

The moderate positive gate turns on the nonvolatile memory. Beyond the drain saturation voltage, the device is in saturation mode. Since the moderate gate voltage is not as high as those in the programming scheme, the floating gate initially is losing some electrons from Drain Avalanche Hot Holes In Injection (DAHHI) leading to lower device threshold voltage and gradually increases on the drain current. The process will continue until a restricted maximum allowed drain current is reached, and the device will self-converge to a specific threshold voltage. Eventually, the erase process reaches a steady state with the maximum drain current and a converged lower threshold voltage.

The Erasing Scheme for PFET Based Nonvolatile Memory:

A method of self-convergent erasing a nonvolatile memory having holes stored in a floating gate comprising: applying a moderate negative gate voltage on the PFET gate to sufficient to turn on the nonvolatile memory; and applying to the PFET drain electrode with a high negative voltage with absolute value that is higher than the one of the saturation voltage to create DAHCI in the drain depleted region.

While with more negative drain voltage beyond the saturation voltage for the PFET based EEPROM, the device is in saturation mode. Since the moderate gate voltage is not as negative as those in the programming scheme, the floating gate initially is losing some holes from Drain Avalanche Hot Electrons Injection (DAHEI) leading to higher device negative threshold voltage (toward more positive side) and gradually increases on the drain current magnitude. The process will continue until a restricted maximum magnitude of allowed drain current is reached and the device will self-converge to a specific threshold voltage. Eventually, the process reaches a steady state with the maximum magnitude of drain current and a converged higher negative threshold voltage.

### BRIEF DESCRIPTION OF THE DRAWINGS

The above objects, and other features and advantages of the present invention will become more apparent after reading the following detailed description when taken in conjunction with the drawings, in which:

FIG. 1A is a diagrammatic cross-section view of a NFET based stacked-gate cell according to the prior art.

FIG. 1B is a diagrammatic cross-section view of a split-gate cell according to the prior art.

FIG. 2A is a diagrammatic cross-section view of a PMOSFET based stacked-gate cell according to the prior art.

FIG. 2B is a diagrammatic cross-section view of a split-gate cell according to the prior art.

FIG. 3A is a diagrammatic cross-section view of an NFET EEPROM programming conditions according to the prior art.

FIG. 3B is a diagrammatic cross-section view of an NFET EEPROM programming conditions according to the present invention.

FIG. 4A is a diagrammatic cross-section view of a PFET EEPROM programming conditions according to the prior art.

FIG. 4B is a diagrammatic cross-section view of a PFET EEPROM programming conditions according to the present invention.

FIG. 5A is a schematic of programming NFET EEPROM according to the present invention.

FIG. 5B is a schematic of programming PFET EEPROM according to the present invention.

FIG. 6A is a diagrammatic cross-section view of a Fowler-Nordheim Tunneling (FNT) erasing for NFET EEPROM according to the prior art.

FIG. 6B is a diagrammatic cross-section view of a Drain-Avalanche-Hot Hole Injection (DAHHI) self-convergent erasing for NFET EEPROM according to the present invention.

FIG. 7A is a diagrammatic cross-section view of a Fowler-Nordheim Tunneling (FNT) erasing for PFET EEPROM according to the prior art.

FIG. 7B is a diagrammatic cross-section view of a Drain-Avalanche-Hot Hole Injection (DAHHI) self-convergent erasing for PFET EEPROM according to the present invention.

FIG. 8A is a schematic of erasing NFET EEPROM with a resistor load attached to high voltage Vddh to limit the maximum allowable device drain current according to the present invention.

FIG. 8B is a schematic of erasing PFET EEPROM with a resistor sink to the ground to limit the maximum allowable device drain current according to the present invention.

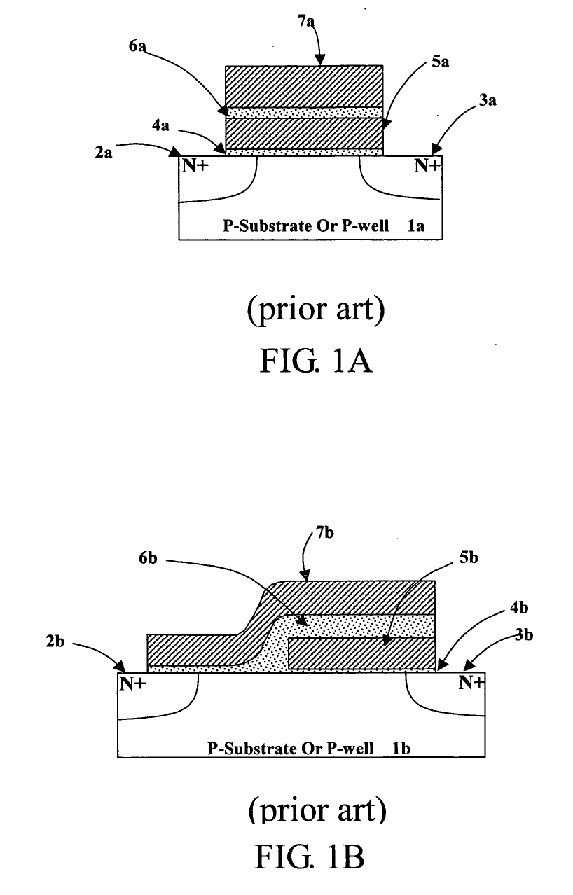

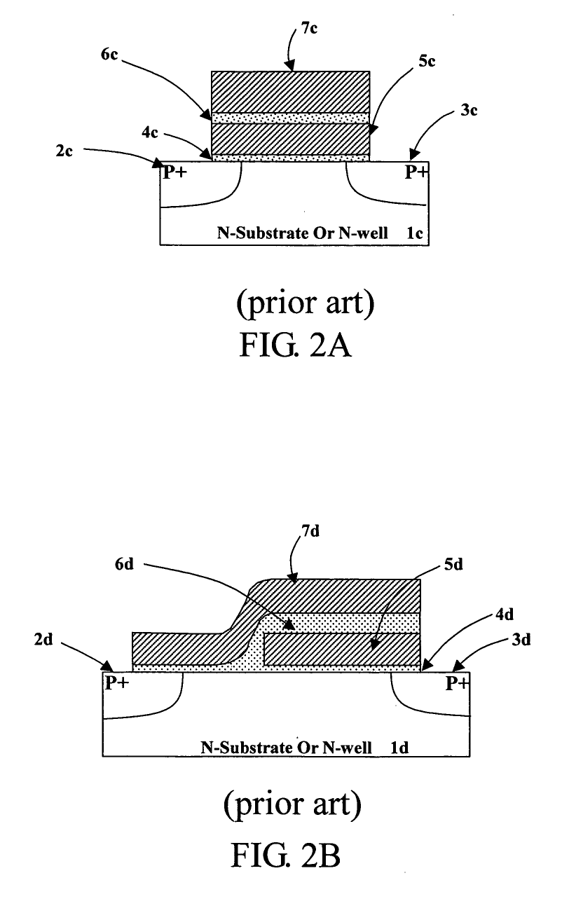

### DESCRIPTION OF THE PREFERRED EMBODIMENT

Method and structure for manufacturing a semiconductor device (such as integrated circuit) or a substrate is described below. In the following description, numerous specific details are set forth in order to provide a thorough understanding of the present invention, and the scope of the present invention is expressly not limited expect as specified in the accompanying claims. One skilled in the relevant art will recognize, however, that the invention may be practiced without one or more of the specific details. In other instances, well known structures, materials, or operations are not shown or described in order to avoid obscuring aspects of the invention.

The present invention includes methods and schematics to achieve high-speed low-voltage programming and self-convergent high-speed low-voltage Erasing for Electrically Erasable Programmable Read-Only Memory (EEPROM). Those of ordinary skill in the art will immediately realize that the embodiments of the present invention described herein in the context of methods and schematics are illustrative only and are not intended to be in any way limiting. Other embodiments of the present invention will readily suggest themselves to such skilled persons having the benefits of this disclosure.

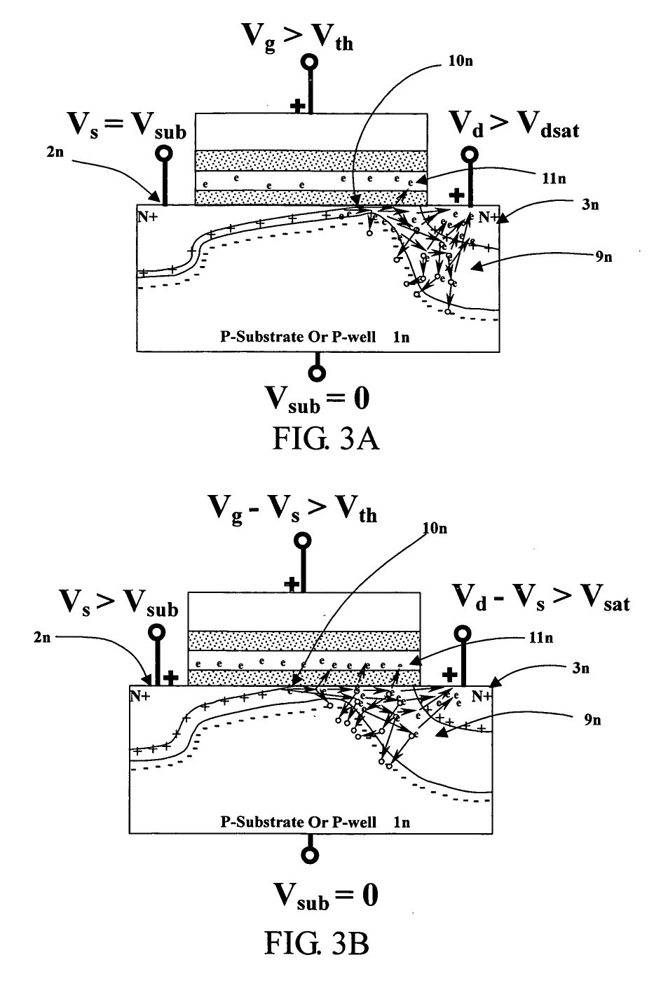

Referring to FIG. 3B, which shows a structure of NFET EEPROM programming scheme according to an embodiment of the present invention. In the preferred embodiment, the NFET is constructed in a P-substrate 1n. A non-trivial voltage, Vs, between source 2n and substrate 1n (assuming P-substrate grounded) is applied to increase the ratio of gate current to the substrate current generated from the Drain-Avalanche-Hot Carriers Injection (DAHCI). To phrase in another words, the positive source voltage relative to substrate creates a reversed biased on the source substrate junction. When the NFET is in saturation mode, the reversed biased source-substrate depletes the junction further and increases the depletion width. The pinch-off point 10n moves toward the source electrode 2n and the edge of depleted substrate region pushes deeper into the substrate 1n. Thus, the reversed source-substrate voltage bias increases the surface electron density and surface impact ionization, and also reduces the possibility for holes to inject into the substrate 1n. The programming efficiency increase with higher surface electron density and less substrate hole current. Therefore, the requirement for programming current and voltage are significantly lower.

Compared with the FIG. 3A, in the embodiment, it is more prominent that the pinch-off point 10n shifts to the source electrode 2n leading to extended surface depleted region 9n toward the drain 3n and the edge of the depleted substrate region pushes deeper into the substrate 1n, when applying the positive voltage to the source electrode 2a. There are more hot electrons jumping into the floating gate than in the conventional structure, therefore the programming speed is also faster than in the conventional scheme.

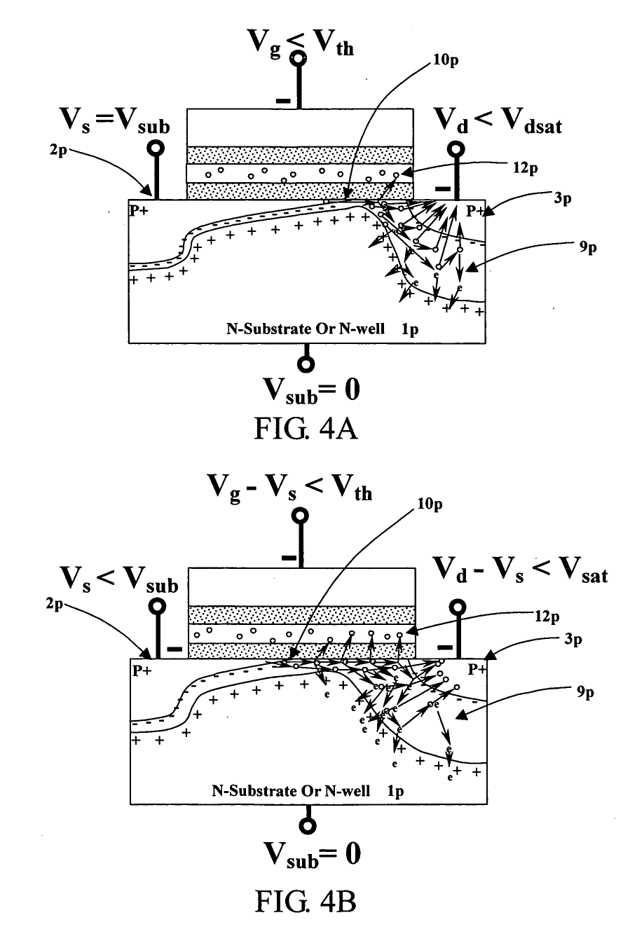

FIG. 4B shows a PFET based nonvolatile memory programming scheme according to another embodiment of the present invention. A negative voltage difference, Vs−Vsub, from the source 2p to substrate 1p (reversed bias for the source-substrate junction) is applied for the PFET based EEPROM. The reversed negative voltage bias between source 2b and substrate 1p is adjusted to increase the ratio of gate current to the substrate current generated from the Drain-Avalanche-Hot Hole Injection (DAHHI).

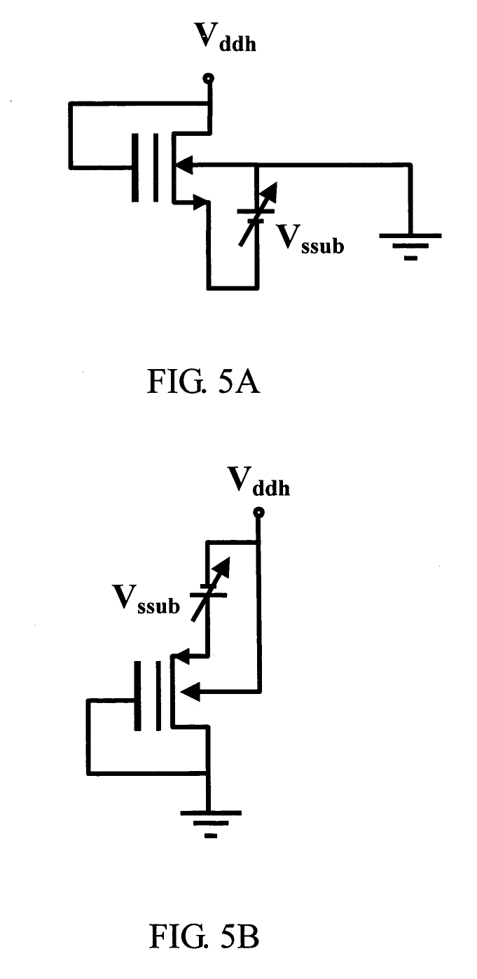

Turning to FIG. 5A, it shows a schematic of programming for NFET type EEPROMs according an embodiment of the present invention. The present invention enables the programming operation with high-speed and low-voltage. A voltage reversed-bias is applied between source and substrate. In the preferred embodiment, the NFET is constructed in a P-substrate. Thus, the substrate is grounded. A positive voltage is applied to create this reversed-bias between N+ source electrode and P-substrate. Both control gate electrode and drain electrode are coupled to a positive high voltage Vddh (substantially 6.5 volts for an EEPROM). The reversed-bias voltage, Vssub, can be adjusted to obtain the maximum ratio of gate current to substrate current. In an EEPROM, the programming scheme can achieve microsecond to hundreds microsecond ranges of programming speed with a reversed-bias voltage of Vssub, approximate 2 volts.

For PFET EEPROM programming, the schematic is set up as shown in FIG. 5B. In this preferred embodiment, the PFET is constructed in an N-well. The N-well is connected to a positive high voltage Vddh. A reversed-bias voltage (negative voltage relative to the N-well) is applied between P+ source electrode and N-well. Both control gate electrode and drain electrode are connected to ground. The reversed-bias voltage can be adjusted to obtain the maximum ratio of gate current to substrate current.

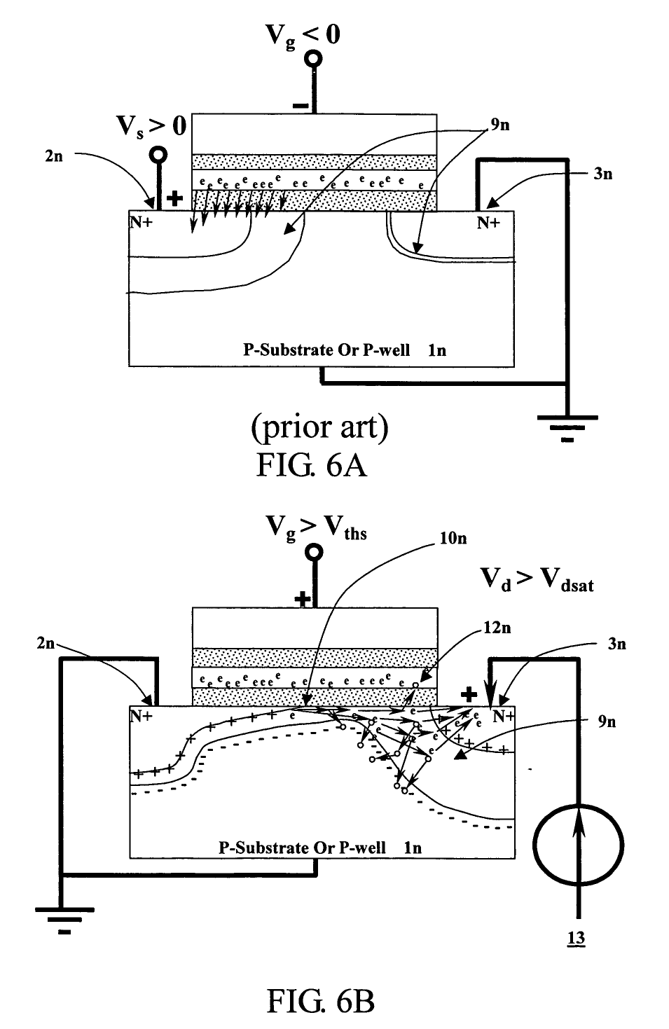

FIG. 6B shows an NFET EEPROMS self-convergent erasing scheme according to one embodiment of the present invention. For the self-convergent low-voltage erasing scheme, the device initiate state shall be in the more positive threshold voltage state (more negative threshold voltage for PFET devices). That is, the devices initially store electrons in floating gate for NFET based EEPROM and store holes in the PFET based EEPROM, respectively. For the NFET EEPROM, a moderate positive gate voltage, Vg, is applied to turn on the device and drain electrode is applied to a high voltage (Vd>Vdsat) to create DAHCI in the drain-depleted region, where Vdsat is the saturation voltage. Beyond the Vdsat, the device is in saturation mode. With a restricted maximum allowed drain current, the device will self-converge to a specific threshold voltage by Avalanche-Hot Holes Injection (DAHHI), when the erase process reaches a steady state.

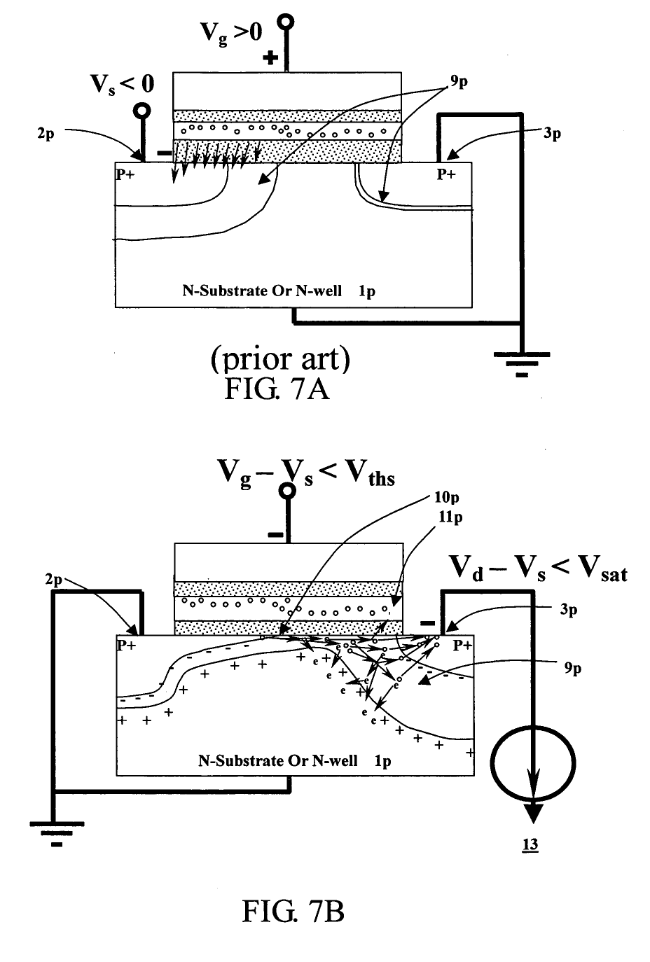

Please refer to FIG. 7B, it shows a PFET EEPROMS self-convergent erasing scheme according to another embodiment of the present invention. While for the PFET based EEPROM, a moderate negative gate voltage, Vg, is applied to turn on the device (Vg−Vs<Vths) and drain electrode 3p is applied with negative voltage relative to the source voltage (Vd−Vs<Vdsat) to create DAHCI in the drain depleted region, where Vdsat is the saturation voltage for PFET. With restricted maximum allowed source to drain current, the device will self-converge to a specific threshold voltage by Avalanche-Hot Electron Injection (DAHEI), when the process reaches a steady state.

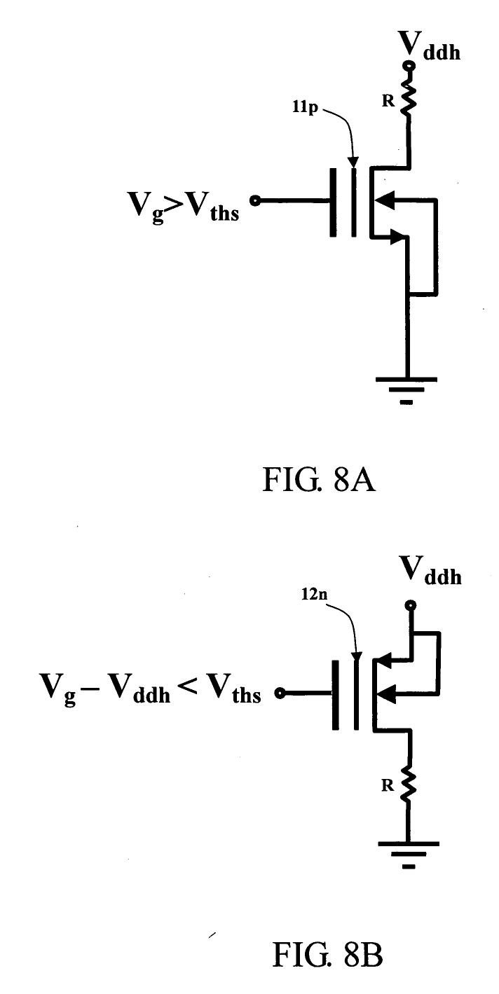

The schematic to achieve self-convergent erase scheme for the NFET embodiment is shown in FIG. 8A. The NFET EEPROM device has been initially programmed to a high threshold voltage state using the previous programming scheme. The drain electrode is connected to a resistor R to a high positive voltage Vddh. N+ source electrode and P-substrate are tied to the ground. The control gate is applied to a control gate voltage, Vg, greater than the saturation threshold voltage. Due to the Drain-Induced-Barrier-Lowering (DIBL), the saturation voltage Vths is much less than its linear threshold voltage. With proper adjustment on the control gate voltage Vg and resistor R, the device is erased down and self-converged to a lower threshold voltage. In an NFET EEPROM, the erase-down to a lower threshold voltage is achieved less than millisecond while the control gate voltage Vg is substantially 0.7 volts, the resistor R is substantially 10 kΩ, and the high voltage Vddh is substantially 6.5 volts.

For PFET EEPROM self-convergent low voltage erasing, the schematic is shown in FIG. 8B. The device has been initially programmed to a more negative threshold voltage by the previous programming scheme. The source electrode and N-well is connected to the positive high voltage Vddh. The drain electrode is connected to a resistor R, and the resistor R is connected to the ground. A voltage Vg to turn on the device is applied to the control gate. That is, the difference between the voltage Vg and the high voltage Vddh is sufficient to turn on the threshold voltage Vths. When the device reaches a steady state in less than milliseconds, a steady state larger threshold voltage Vth (a negative threshold voltage shifting toward the positive side) can be obtained.

Note in this preferred embodiment, the programming and erasing methods for both NFET and PFET only require one positive high voltage supply. It dramatically reduces the complicity of charge pumping circuit design. Although the parameter windows for varieties of EEPROMs may vary depending on the device structures, geometries, and material properties, these schemes can be applied to all varieties of EEPROMs.

In conclusion, the present invention provides a high efficient programming scheme for both NFET based and PFET based EEPROMs. Due to the improvement of the programming efficiency, the scheme can achieve high speed and low voltage programming for EEPROMs. The programming scheme also reduces the disturbance issue for the neighboring EEPROM cells. The present invention also provides a self-convergent and low-voltage erasing scheme. Due to the self-convergence and low-voltage, the scheme can provide very narrow threshold voltage spreads after erasing operations with fast erasing speed. Although the device programming-erasing windows may vary with different EEPROM device structures and geometries, the basic idea of the present invention schemes shall be applied.

The specific embodiments have been illustrated and described, it will be obvious to those skilled in the art that various modifications may be made without departing from what is intended to be limited solely by the appended claims.

What is claimed is:

1. A method of programming a nonvolatile memory, comprising:
applying on a source a positive source voltage relative to a substrate to create a reversed-bias voltage on a source-substrate junction; and
applying a first and a second positive voltages to a control gate and a drain, respectively.

2. The method in claim 1, wherein said nonvolatile memory is an NFET based EEPROM.

3. The method in claim 1, wherein the difference between said first positive voltage and said positive source voltage is greater than the threshold voltage of said nonvolatile memory.

4. The method in claim 1, wherein said second positive voltage relative to the positive source voltage is sufficient large to operate said nonvolatile memory in saturation mode.

5. A scheme of programming a nonvolatile memory, said nonvolatile memory comprises:
a positive high voltage applied to a control gate and a drain;
a reverse-bias voltage applied between a substrate and a source, wherein said reverse-bias voltage is adjustable to obtain the maximum gate current and less substrate current.

6. The scheme in claim 5, wherein said nonvolatile memory is an NFET based EEPROM.

7. The scheme in claim 5, wherein said substrate is coupled to ground voltage.

8. A method of programming a nonvolatile memory comprising:
applying on a source a negative source voltage relative to a substrate to create a reversed-bias voltage on a source substrate junction; and
applying a first and a second negative voltages to a control gate and a drain, respectively.

9. The method in claim 8, wherein said nonvolatile memory is a PFET based EEPROM.

10. The method in claim 8, wherein the absolute value of the difference between said first negative voltage and said negative source voltage is greater than the one of the threshold voltage of said nonvolatile memory.

11. The method in claim 8, wherein the absolute value of said second negative voltage relative to said negative source voltage is sufficient large to operate said nonvolatile memory in saturation mode.

12. The scheme in claim 8, wherein said substrate is coupled to ground voltage.

13. A scheme of programming a nonvolatile memory, said nonvolatile memory comprises:
a positive high voltage applied to a substrate or Nwell; and
a reversed-bias voltage applied between said source and said substrate, wherein said reversed-bias voltage is adjustable to obtain the maximum gate current and less substrate current.

14. The scheme in claim 13, wherein said nonvolatile memory is a PFET based EEPROM.

15. The scheme in claim 13, wherein a control gate and a drain of said nonvolatile memory are coupled to ground voltage.

16. A method of self-convergent erasing a nonvolatile memory having carriers stored in a floating gate comprising:
applying a moderate positive gate voltage on said floating gate to turn on said nonvolatile memory;
applying to a drain with high voltage that is higher than a saturation voltage to create DAHCI in a drain depletion region.

17. The method in claim 16, furthering comprising grounding a source and a substrate.

18. The method in claim 16, wherein said nonvolatile memory is an NFET based EEPROM.

19. The method in claim 16, wherein said moderate positive gate is higher than the threshold voltage of said nonvolatile memory.

20. The method in claim 16, wherein a maximum drain current is generated in said self-convergent erasing.

21. A scheme of self-convergent erasing a nonvolatile memory having carriers stored in a floating gate comprising:
a current load said a resistor coupled between a drain and a positive high voltage; and
a control gate voltage applied to said floating gate; and
wherein said control gate voltage is adjustable, thereby erasing down and self-converged to a lower threshold voltage.

22. The scheme in claim 21, wherein a source and a substrate coupled to ground voltage.

23. The scheme in claim 21, wherein said nonvolatile memory is an NFET based EEPROM.

24. The scheme in claim 21, wherein said control gate voltage is higher than the saturation threshold voltage of said nonvolatile memory.

25. A method of self-convergent erasing a nonvolatile memory having carriers stored in a floating gate comprising:
applying a moderate negative gate voltage on said gate to sufficiently turn on said nonvolatile memory;
applying to drain electrode with a negative voltage, wherein the absolute value of said drain voltage relative to said source voltage is higher than the one of said saturation voltage to create DAHCI in a drain depletion region.

26. The method in claim 25, furthering comprising applying grounded voltage to a source and a substrate.

27. The method in claim 25, wherein said nonvolatile memory is a PFET based EEPROM.

28. The method in claim 25, wherein said moderate negative gate voltage is lower than the threshold voltage of said nonvolatile memory.

29. The method in claim 25, wherein a maximum drain current is generated in said self-convergent erasing.

30. A scheme of self-convergent erasing a nonvolatile memory having carriers stored in a floating gate comprising:
a current sink said a resistor coupled between a drain and a ground;
a positive high voltage applied to a source and a substrate; and
a gate voltage coupled to said floating gate; and
wherein said control gate voltage is set, thereby erasing down and self-converged to a lower threshold voltage.

31. The scheme in claim 30, wherein a source and a substrate coupled to a positive high voltage.

32. The scheme in claim 30, wherein said nonvolatile memory is a PFET based EEPROM.

33. The scheme in claim 30, wherein said the absolute value of the differences between said control gate voltage and said positive high source voltage is larger than the one of the saturation threshold voltage of said nonvolatile memory.
